(19) United States
(12) Patent Application Publication
(10) Pub. No.: US 2025/0341598 A1
(43) Pub. Date: Nov. 6, 2025

(54) SPHERICAL MAGNETIC RESONANCE IMAGING BASED ON THREE-DIMENSIONAL RADIAL DATA SAMPLING

(71) Applicant: Abbas NASIRAEI MOGHADDAM, Tehran (IR)

(72) Inventors: Abbas NASIRAEI MOGHADDAM, Tehran (IR); Majid GHASEMI, Tehran (IR)

(73) Assignee: Abbas NASIRAEI MOGHADDAM, Tehran (IR)

(21) Appl. No.: 19/017,818

(22) Filed: Jan. 13, 2025

Related U.S. Application Data
(63) Continuation-in-part of application No. PCT/IB2024/054361, filed on May 5, 2024.

(51) Int. Cl. G01R 33/48; G01R 33/56

(52) U.S. Cl. CPC G01R 33/4826; G01R 33/5608

(57) ABSTRACT

A method for spherical magnetic resonance imaging (MRI) based on three-dimensional (3D) radial data sampling. The method includes acquiring a plurality of frequency samples of an object in a spatial frequency domain according to a 3D radial sampling scheme and reconstructing a 3D image of the object in a space domain by applying a spherical Fourier transform (SFT) to the plurality of frequency samples. An MRI scanner is utilized for acquiring the plurality of frequency samples.

### CROSS-REFERENCE TO RELATED APPLICATION

This application is a continuation-in-part of PCT/IB2024/054361 filed on May 5, 2024 and entitled “SPHERICAL MAGNETIC RESONANCE IMAGING BASED ON THREE-DIMENSIONAL RADIAL DATA SAMPLING,” which is incorporated herein by reference in its entirety.

### TECHNICAL FIELD

The present disclosure generally relates to medical imaging, and particularly, to magnetic resonance imaging.

### BACKGROUND OF THE INVENTION

Magnetic resonance imaging (MRI) is a well-known medical imaging modality that allows for a non-invasive assessment of the anatomy and function of the heart, without exposure to ionizing radiation. MRI offers not only high spatial resolution, but also an excellent soft-tissue contrast. MRI is recognized as a leading modality for diagnostic imaging of numerous common diseases.

Outstanding properties of MRI are, however, countered by a number of limitations, including time-consuming data acquisition, which results in lengthy examinations compared to other imaging techniques. A straightforward approach for resolving this issue may be to reduce the number of acquired data samples as much as possible. It has been shown that radial data sampling methods may allow for a significant reduction of data samples without a major degradation of image quality compared to Cartesian data sampling. However, conventional reconstruction methods have to interpolate radially sampled data prior to perform image reconstruction. Therefore, interpolated data may degrade image reconstruction quality.

There is, therefore, a need for a method for MRI image reconstruction without a need for interpolating raw data (in the spatial frequency domain). There is also a need for an MRI system that may provide images from radially sampled data without a need for interpolated data for image reconstruction.

### SUMMARY OF THE INVENTION

This summary is intended to provide an overview of the subject matter of this patent, and is not intended to identify essential elements or key elements of the subject matter, nor is it intended to be used to determine the scope of the claimed implementations. The proper scope of this patent may be ascertained from the claims set forth below in view of the detailed description below and the drawings.

In one general aspect, the present disclosure describes an exemplary method for spherical magnetic resonance imaging (MRI) based on three-dimensional (3D) radial data sampling. An exemplary method may include acquiring a plurality of frequency samples of an object in a spatial frequency domain according to a 3D radial sampling scheme and reconstructing a 3D image of the object in a space domain by applying a spherical Fourier transform (SFT) to the plurality of frequency samples. An exemplary MRI scanner may be utilized for acquiring the plurality of frequency samples.

In an exemplary embodiment, acquiring the plurality of frequency samples according to the 3D radial sampling scheme may include acquiring the plurality of frequency samples at regular intervals along a plurality of radial paths from a center of a 3D k-space. In an exemplary embodiment, acquiring the plurality of frequency samples according to the 3D radial sampling scheme may further include determining one of a number of the plurality of radial paths or an angular distance between adjacent radial paths of the plurality of radial paths based on a radial distance that may be associated with a given spatial resolution of the 3D image.

In an exemplary embodiment, reconstructing the 3D image may include obtaining a first vector of spherical harmonic coefficients by calculating a respective plurality of spherical harmonic coefficients in the spatial frequency domain for each of the plurality of frequency samples and obtaining a second vector of spherical harmonic coefficients by calculating a spherical Hankel transform of the first vector. An exemplary second vector may include a respective plurality of spherical harmonic coefficients in the space domain for each of a plurality of space samples of the 3D image. In an exemplary embodiment, reconstructing the 3D image may further include obtaining the 3D image by calculating a spherical harmonics expansion of each of the plurality of space samples based on the respective plurality of spherical harmonic coefficients in the space domain.

Other exemplary systems, methods, features and advantages of the implementations will be, or will become, apparent to one of ordinary skill in the art upon examination of the following figures and detailed description. It is intended that all such additional systems, methods, features and advantages be included within this description and this summary, be within the scope of the implementations, and be protected by the claims herein.

### BRIEF DESCRIPTION OF DRAWINGS

The drawing figures depict one or more implementations in accord with the present teachings, by way of example only, not by way of limitation. In the figures, like reference numerals refer to the same or similar elements.

FIG. 1A shows a flowchart of a method for spherical magnetic resonance imaging (MRI) based on three-dimensional (3D) radial data sampling, consistent with one or more exemplary embodiments of the present disclosure.

FIG. 1B shows a flowchart for reconstructing a 3D image, consistent with one or more exemplary embodiments of the present disclosure.

FIG. 2 shows a schematic of a system for spherical MRI based on 3D radial data sampling, consistent with one or more exemplary embodiments of the present disclosure.

FIG. 3 shows a schematic of a cross-section of a 3D radial sampling scheme, consistent with one or more exemplary embodiments of the present disclosure.

FIG. 4 shows a schematic of two adjacent points on a sphere in a space domain, consistent with one or more exemplary embodiments of the present disclosure.

FIG. 5 shows a high-level functional block diagram of a computer system, consistent with one or more exemplary embodiments of the present disclosure.

### DETAILED DESCRIPTION OF THE INVENTION

In the following detailed description, numerous specific details are set forth by way of examples in order to provide a thorough understanding of the relevant teachings. However, it should be apparent that the present teachings may be practiced without such details. In other instances, well known methods, procedures, components, and/or circuitry have been described at a relatively high-level, without detail, in order to avoid unnecessarily obscuring aspects of the present teachings.

The following detailed description is presented to enable a person skilled in the art to make and use the methods and devices disclosed in exemplary embodiments of the present disclosure. For purposes of explanation, specific nomenclature is set forth to provide a thorough understanding of the present disclosure. However, it will be apparent to one skilled in the art that these specific details are not required to practice the disclosed exemplary embodiments. Descriptions of specific exemplary embodiments are provided only as representative examples. Various modifications to the exemplary implementations will be readily apparent to one skilled in the art, and the general principles defined herein may be applied to other implementations and applications without departing from the scope of the present disclosure. The present disclosure is not intended to be limited to the implementations shown, but is to be accorded the widest possible scope consistent with the principles and features disclosed herein.

Herein is disclosed an exemplary method for image reconstruction in magnetic resonance imaging (MRI). An exemplary method may include three-dimensional (3D) radial data sampling of an object in the spatial frequency domain. Exemplary data samples may be acquired at regular intervals along radial paths. A spherical Fourier transform (SFT) may then be applied to exemplary acquired data samples. For this purpose, spherical harmonic coefficients of an expansion of data samples in the frequency domain may be obtained. Afterwards, spherical harmonic coefficients of an expansion of reconstructed data samples in the space domain may be obtained by applying a spherical Hankel transform to the spherical harmonic coefficients in the frequency domain. Finally, an exemplary 3D image may be obtained by calculating the expansion of reconstructed data samples in the space domain by utilizing the spherical harmonic coefficients in the space domain. An exemplary method may also include steps for accelerating computations through required resolution in a limited volume of the 3D image. For this purpose, an exemplary upper limit may be determined for the expansion of reconstructed data samples according to a given spatial resolution of the 3D image. An exemplary method may also include steps for accelerating data acquisition. For this purpose, a number of exemplary along radial paths may be reduced in the frequency domain according to the given spatial resolution inside a limited region of the 3D image. As a result, an exemplary 3D image may be obtained in the space domain directly from acquired data samples in the frequency domain, without a need for interpolating the acquired data samples.

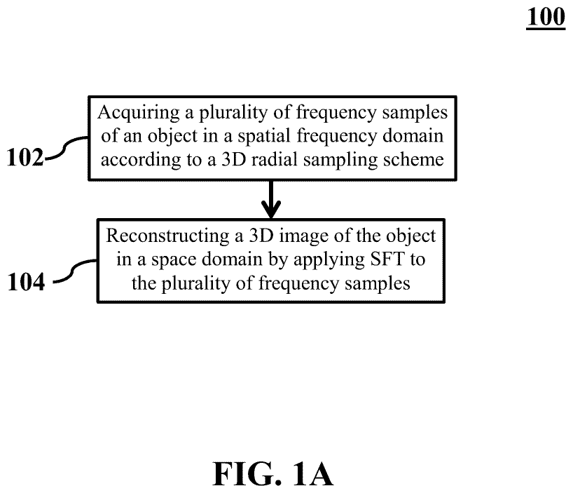

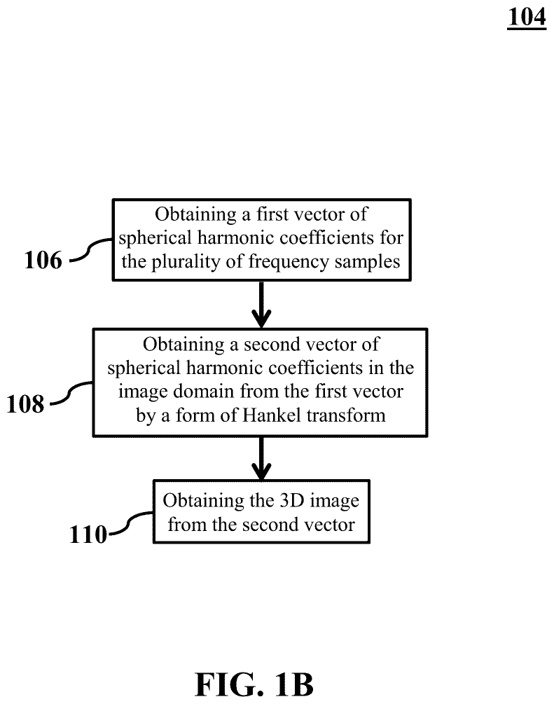

FIG. 1A shows a flowchart of a method for spherical MRI based on 3D radial data sampling, consistent with one or more exemplary embodiments of the present disclosure. An exemplary method 100 may include acquiring a plurality of frequency samples of an object in a spatial frequency domain according to a 3D radial sampling scheme (step 102) and reconstructing a 3D image of the object in a space domain by applying an SFT to the plurality of frequency samples (step 104).

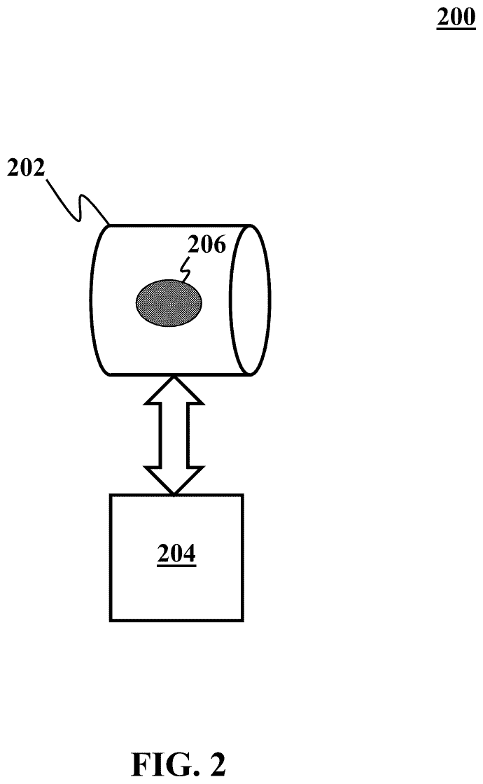

FIG. 2 shows a schematic of a system for spherical MRI based on 3D radial data sampling, consistent with one or more exemplary embodiments of the present disclosure. An exemplary system 200 may include an MRI scanner 202 and a processor 204. In an exemplary embodiment, different steps of method 100 may be implemented by utilizing system 200.

Referring to FIGS. 1A and 2, in an exemplary embodiment, step 102 may include acquiring a plurality of frequency samples of an object 206 in a spatial frequency domain according to a 3D radial sampling scheme. In an exemplary embodiment, MRI scanner 202 may be utilized for acquiring the plurality of frequency samples.

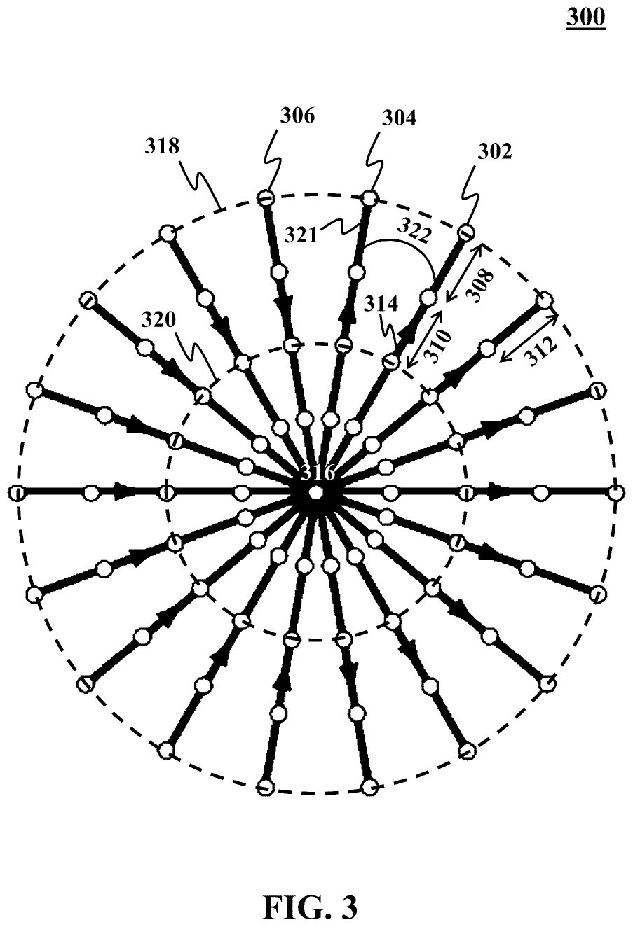

In further detail with respect to step 102, FIG. 3 shows a schematic of a cross-section of a 3D radial sampling scheme, consistent with one or more exemplary embodiments of the present disclosure. An exemplary 3D radial sampling scheme 300 may include acquiring a plurality of frequency samples (for example, frequency samples 302, 304, and 306) at regular intervals (for example, intervals 308, 310, and 312) along a plurality of radial paths (for example, a radial path 314) from a center 316 of a 3D k-space. In an exemplary embodiment, “regular intervals” may refer to intervals with a same pattern on different radial paths (also called “spokes”). In other words, corresponding intervals on different radial paths (for example, intervals 308 and 312) may have equal lengths. As a result, an exemplary plurality of frequency samples may be divided into different sets of frequency samples that may be located on corresponding spherical shells centered at center 316. For example, frequency samples 302, 304, and 306 may be located on a spherical shell 318. In an exemplary embodiment, different spherical shells may contain an equal number of frequency samples. For example, a number of frequency samples on a spherical shell 320 may be equal to a number of frequency samples on spherical shell 318. In an exemplary embodiment, 3D radial sampling scheme 300 may be implemented via different techniques, such as diagonal (full) or radial (half spoke) data acquisition methods. In an exemplary embodiment, 3D radial sampling scheme 300 may further be performed along a uniform or a non-uniform distribution of spokes. In an exemplary embodiment, the 3D k-space may refer to a 3D space over which a Fourier transform of a spatial function may be represented at spatial frequencies of plane waves of the Fourier transform.

For further detail regarding step 104, FIG. 1B shows a flowchart for reconstructing a 3D image, consistent with one or more exemplary embodiments of the present disclosure. In an exemplary embodiment, reconstructing the 3D image in step 104 may include obtaining a first vector of spherical harmonic coefficients for the plurality of frequency samples (step 106), obtaining a second vector of spherical harmonic coefficients from the first vector (step 108), and obtaining the 3D image from the second vector (step 110).

In an exemplary embodiment, obtaining the first vector of harmonic coefficients in step 106 may include calculating a respective plurality of spherical harmonic coefficients in the spatial frequency domain for each magnitude of the plurality of frequency samples for all of the plurality of radial paths. An exemplary frequency function F(ρ,θ_{ρ},ϕ_{ρ}) may be represented by a spherical harmonic expansion according to an operation defined by the following:

$$F ( ρ , {θ}_{ρ} , {ϕ}_{ρ} ) = {\sum }_{l = 0}^{∞} {\sum }_{m = - l}^{l} {F}_{l}^{m} ( ρ ) {Y}_{l}^{m} ( {θ}_{ρ} , {ϕ}_{ρ} ) \qquad Equation ( 1 )$$

where ρ is a radial frequency distance of frequency sample F(ρ,θ_{ρ},ϕ_{ρ}),θ_{ρ} is a polar angle of radial frequency distance ρ, and ϕ₉₂ is an azimuthal angle of radial frequency distance ρ. In an exemplary embodiment,

$${F}_{l}^{m} ( ρ )$$

may be referred to as an (l, m)^{th} spherical harmonic coefficient of in the spherical harmonic expansion of frequency sample F(ρ,θ_{ρ},ϕ_{ρ})according to Equation (1), where l and m are integers. In an exemplary embodiment, (l, m)^{th} spherical harmonic coefficient

$${F}_{l}^{m} ( ρ )$$

may be calculated according to an operation defined by the following:

$${F}_{l}^{m} ( ρ ) = {\int }_{0}^{2 π} {\int }_{0}^{π} F ( ρ , {θ}_{ρ} , {ϕ}_{ρ} ) \overline{{Y}_{l}^{m} ( {θ}_{ρ} , {ϕ}_{ρ} )} sin {θ}_{ρ} d {θ}_{ρ} d {ϕ}_{ρ} \qquad Equation ( 2 )$$

where

$$\overline{{Y}_{l}^{m} ( \cdot )}$$

is a complex conjugate of a spherical harmonic function

$${Y}_{l}^{m} ( \cdot )$$

of order l and degree m. In an exemplary embodiment, spherical harmonic function

$${Y}_{l}^{m} ( {θ}_{ρ} , {ϕ}_{ρ} )$$

is given by the following:

$${Y}_{l}^{m} ( {θ}_{ρ} , {ϕ}_{ρ} ) = \sqrt{\frac{2 l + 1}{4 π} \frac{( l - m ) !}{( l + m ) !}} {P}_{l}^{m} ( cos {θ}_{ρ} ) {e}^{im {θ}_{ρ}} \qquad Equation ( 3 )$$

where

$${P}_{l}^{m} ( \cdot )$$

is an associated Legendre function and i is the imaginary unit. In an exemplary embodiment, (l, m)^{th} spherical harmonic coefficient

$${F}_{l}^{m} ( ρ )$$

may form an (l,m,ρ)^{th} element of an exemplary first vector F.

In an exemplary embodiment, obtaining a second vector f of spherical harmonic coefficients in step 108 may include calculating a spherical Hankel transform of first vector F according to an operation defined by the following:

$${f}_{l}^{m} ( r ) = {i}^{l} {S}_{l} \{ {F}_{l}^{m} ( ρ ) \} \qquad Equation ( 4 )$$

where r is a radial space distance of a space sample f(r,θᵣ,ϕᵣ) of a plurality of space samples of the 3D image in the space domain where θᵣ and ϕᵣ are the polar angle and the azimuthal angle of space sample f(r,θᵣ,ϕᵣ), respectively, Sₗ{⋅} is an l^{th} order spherical Hankel transform, and

$${f}_{l}^{m} ( r )$$

may form an (l,m)^{th} element of second vector f. In an exemplary embodiment,

$${f}_{l}^{m} ( r )$$

may be an (l,m)^{th} spherical harmonic coefficient in a spherical harmonic expansion of space sample f(r,θᵣ, ϕᵣ) in the space domain. In other words, an exemplary second vector f may include a respective plurality of spherical harmonic coefficients in the space domain for each of the plurality of space samples, for example, space sample f(r,θᵣ,ϕᵣ), of the 3D image.

In an exemplary embodiment, obtaining the 3D image in step 110 may include calculating a spherical harmonics expansion of each of the plurality of space samples based on the respective plurality of spherical harmonic coefficients in the space domain. For example, a spherical harmonics expansion of space sample f(r,θᵣ,ϕᵣ) may be obtained based on spherical harmonic coefficients

$${f}_{l}^{m} ( r )$$

according to an defined by the following:

$$f ( r , {θ}_{r} , {ϕ}_{r} ) = {\sum }_{l = 0}^{L} {\sum }_{m = - l}^{l} {f}_{l}^{m} ( r ) {Y}_{l}^{m} ( {θ}_{r} , {ϕ}_{r} ) \qquad Equation ( 5 )$$

where L is an upper limit for the spherical harmonics expansion of space sample f(r,θᵣ,ϕᵣ)).

If, in an exemplary embodiment, upper limit L is selected large enough, space samples f(r,θᵣ,ϕᵣ)may represent a valid estimation of an SFT of frequency samples F(ρ,θ_{ρ},ϕ_{ρ}). Therefore, in an exemplary embodiment, obtaining the 3D image may further include calculating upper limit L according to a given spatial resolution inside a limited spherical area of the 3D image.

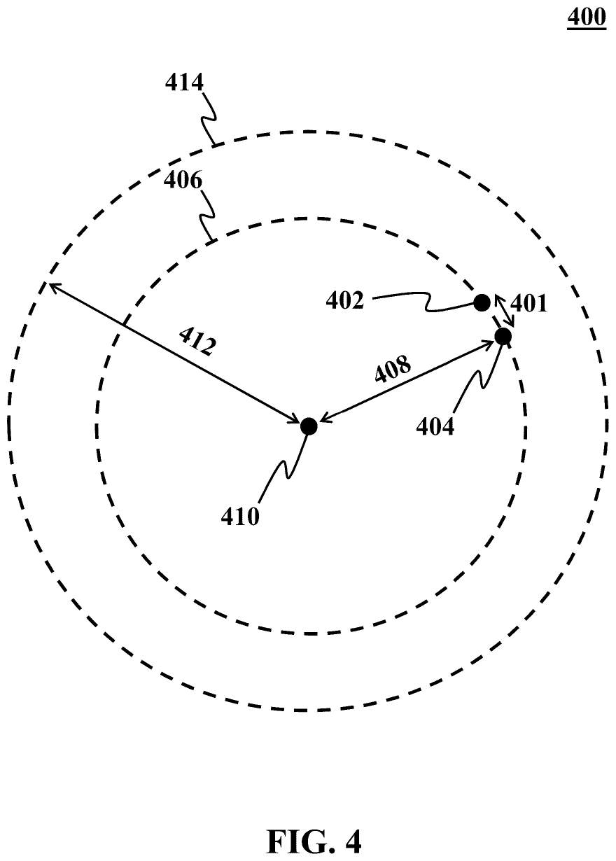

FIG. 4 shows a schematic of two adjacent points on a sphere in a space domain, consistent with one or more exemplary embodiments of the present disclosure. Referring to FIGS. 2 and 4, an exemplary 3D image of object 206 may be reconstructed in a space domain 400. An exemplary spatial resolution res of the 3D image may be defined as a spatial distance 401 between two adjacent points 402 and 404 that are located on a sphere 406 with a radius 408 from a center 410 of space domain 400. In an exemplary embodiment, spatial distance 401 may be a minimum distance between adjacent points 402 and 404 at which the two adjacent points may be distinguished as separate points in the 3D image. In an exemplary embodiment, a lower limit of spatial resolution res may be determined based on a maximum value of spatial sampling frequency of 3D radial sampling scheme 300.

In an exemplary embodiment, obtaining the 3D image in step 110 may further include calculating upper limit L. Theoretically, upper limit L may be infinity. In practice, however, if 3D radial sampling scheme 300 satisfies the Nyquist condition, upper limit L may be defined by the following:

$${L}_{nyq} = ⌊ \frac{{j}_{1 , 1}}{2 {sin}^{- 1} ( \frac{res}{2 R} )} - 1 ⌋ \qquad Equation ( 6 )$$

where L_{nyq} represents a value of upper limit L that satisfies the Nyquist condition, j_{1,1} is the first root of the first order Bessel function of the first kind, and R represents a radius 412 of a field of view (FOV) 414 of MRI scanner 202. In an exemplary embodiment, for a limited spherical region of interest (ROI) inside the 3D image, upper limit L may be calculated according to an operation defined by the following:

$$L > \frac{C}{2 {sin}^{- 1} ( \frac{res}{2 {r}_{0}} )} \qquad Inequation ( 1 )$$

where C is a constant, r₀ is a radial distance associated with given spatial resolution res. Inequation (1) shows that upper limit L may be inversely proportional to the angular resolution (given by term

$$2 {sin}^{- 1} ( \frac{res}{2 {r}_{0}} ) )$$

of the 3D image in the space domain. In an exemplary embodiment, constant C may be set to 3.8317 that is an approximation of the first root of the first order Bessel function of the first kind (i.e., j_{1,1}). In an exemplary embodiment, radial distance r₀ may be equal to a length of radius 408 of sphere 406 inside which given spatial resolution res is sought. As a result, in an exemplary embodiment, radial distance r₀ may determine an exemplary ROI inside the 3D image in which given spatial resolution res may be equal to or larger than an achievable resolution of the 3D image. In an exemplary embodiment, the right side of Inequation (1) may define a lower threshold down to which upper limit L may be reduced from upper limit L_{nyq} when given spatial resolution res may have to be maintained inside an exemplary ROI with radial distance r₀. In other words, Inequation (1) defines a criterion on how far upper limit L may be reduced so that image reconstruction may be accelerated with insignificant harm to an exemplary image reconstruction process.

Referring again to FIGS. 1A, 2, 3, and 4, in an exemplary embodiment, acquiring the plurality of frequency samples according to 3D radial sampling scheme 300 in step 102 may further include determining a number of the plurality of radial paths or an angular distance between adjacent radial paths of the plurality of radial paths based on radial distance ro. In an exemplary embodiment, if radial distance r₀ is selected smaller than a radius 412 of a field of view (FOV) 414 of MRI scanner 202 (that is, an exemplary ROI is smaller than FOV 414), it may be possible to accelerate the data acquisition process of step 102 above by limiting the number of the plurality of radial paths (shown in FIG. 3). In an exemplary embodiment, when an exemplary ROI is smaller than FOV 414, given spatial resolution res may be preserved inside the ROI despite using a lower number of radial paths for data acquisition since a lower number of frequency samples may have to be obtained for an exemplary ROI compared to FOV 414.

In an exemplary embodiment, the number of the plurality of radial paths may be reduced by increasing an angular distance between adjacent radial paths of the plurality of radial paths, thereby accelerating the data acquisition and consequently the imaging process. In an exemplary embodiment, for each respective radial path of the plurality of radial paths, an “adjacent radial path” may be defined as a radial path of the plurality of radial paths that may have an angular distance from the respective radial path that is smallest among all angular distances between the respective radial path and other radial paths of the plurality of radial paths which reside within a wedge volume formed by two surfaces intersecting at the respective radial path at an angle of about 60 degrees. For example, a radial path 321 may be an adjacent radial path of radial path 314. In an exemplary embodiment, a statistical distribution for an angular distance 322 between adjacent radial paths 314 and 321 may be determined according to an operation defined by the following:

$$mean ( Δψ ) \leq 2 \times {sin}^{- 1} ( \frac{res}{2 {r}_{0}} ) \qquad Inequation ( 2 a )$$

$$std ( Δψ ) \leq 0.3 \times {sin}^{- 1} ( \frac{res}{2 {r}_{0}} ) \qquad Inequation ( 2 b )$$

where ΔΨ represents angular distance 322, mean (ΔΨ) is an average value of angular distance 322, and std (ΔΨis a standard deviation of angular distance 322. In an exemplary embodiment, the right side of Inequations (2a) and (2b) may define an upper threshold for angular distance 322 up to which the mean of angular distance 322 may be increased from when given spatial resolution res may have to be maintained inside an exemplary ROI with radial distance r₀. Therefore, in an exemplary embodiment, angular distance 322 may be increased as long as 4 substantially satisfies Inequations (2a) and (2b), thereby reducing the number of the plurality of radial paths.

In an exemplary embodiment, Inequations (2a) and (2b) above may be equivalently represented in the frequency domain according to a set of operations defined by the following:

$$mean ( Δψ ) \leq 2 \times {sin}^{- 1} ( \frac{Δ k}{2 {ρ}_{0}} ) \qquad Inequation ( 3 a )$$

$$std ( Δψ ) \leq 0.3 \times {sin}^{- 1} ( \frac{Δ k}{2 {ρ}_{0}} ) \qquad Inequation ( 3 b )$$

where ρ₀ is a radius of a spherical region in the frequency domain in which the Euclidean distance between exemplary adjacent samples is equal to or smaller than Δk. In an exemplary embodiment, spatial frequency resolution Δk may be determined based on radius 412 of FOV 414.

In an exemplary embodiment, when the plurality of radial paths are arranged according to a substantially uniform angular distribution, if 3D radial sampling scheme 300 satisfies the Nyquist condition, the number of the plurality of radial paths may be given by the following:

$${N}_{nyq} = \frac{2 π}{\sqrt{3}} {( \frac{2 R}{res} )}^{2} \qquad Equation ( 7 )$$

where N_{nyq} is a lower threshold of the number of the plurality of radial paths that may satisfy the Nyquist condition. In an exemplary embodiment, the “uniform angular distribution” of the plurality of radial paths may refer to a distribution of the plurality of radial paths in the frequency domain that may uniformly cover the frequency domain. In an exemplary embodiment, for a limited spherical ROI inside the 3D image, the number of the plurality of radial paths may be determined according to the following:

$$N \geq \frac{2 π}{K} {( \frac{2 {r}_{0}}{res} )}^{2} \qquad Inequation ( 4 a )$$

where N is the number of the plurality of radial paths and K is a constant which may be set to \sqrt{3}. In an exemplary embodiment, Inequation (4a) above may be equivalently represented in the frequency domain according to an operation defined by the following:

$$N \geq \frac{2 π}{K} {( \frac{2 {ρ}_{0}}{Δ k} )}^{2} \qquad Inequation ( 4 b )$$

As a result, in an exemplary embodiment, the data acquisition process of step 102 may be accelerated by incorporating the condition of Inequation (4a) or Inequation (4b). In an exemplary embodiment, acquiring the plurality of frequency samples according to 3D radial sampling scheme 300 in step 102 may include arranging the plurality of radial paths according to a substantially uniform angular distribution and determining number N of the plurality of radial paths according to an operation defined by Inequation (4a) or Inequation (4b) above. In an exemplary embodiment, the right side of Inequations (4a) and (4b) may define a lower threshold for number N of the plurality of radial paths down to which number N of the plurality of radial paths may be reduced from threshold N_{nyq} when given spatial resolution res may have to be maintained inside an exemplary ROI with radial distance r₀. Therefore, in an exemplary embodiment, number N of the plurality of radial paths may be reduced as long as N substantially satisfies Inequation (4a) or Inequation (4b).

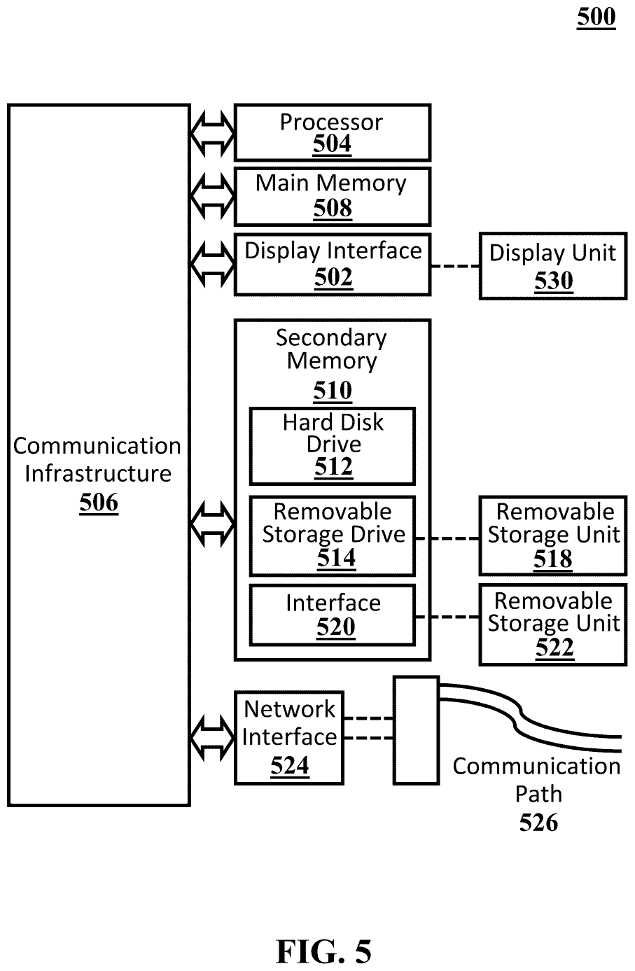

FIG. 5 shows an example computer system 500 in which an embodiment of the present invention, or portions thereof, may be implemented as computer-readable code, consistent with exemplary embodiments of the present disclosure. For example, method 100 may be implemented in computer system 500 using hardware, software, firmware, tangible computer readable media having instructions stored thereon, or a combination thereof and may be implemented in one or more computer systems or other processing systems. Hardware, software, or any combination of such may embody any of the modules and components in FIGS. 1A-2.

If programmable logic is used, such logic may execute on a commercially available processing platform or a special purpose device. One ordinary skill in the art may appreciate that an embodiment of the disclosed subject matter can be practiced with various computer system configurations, including multi-core multiprocessor systems, minicomputers, mainframe computers, computers linked or clustered with distributed functions, as well as pervasive or miniature computers that may be embedded into virtually any device.

For instance, a computing device having at least one processor device and a memory may be used to implement the above-described embodiments. A processor device may be a single processor, a plurality of processors, or combinations thereof. Processor devices may have one or more processor “cores.”

An embodiment of the invention is described in terms of this example computer system 500. After reading this description, it will become apparent to a person skilled in the relevant art how to implement the invention using other computer systems and/or computer architectures. Although operations may be described as a sequential process, some of the operations may in fact be performed in parallel, concurrently, and/or in a distributed environment, and with program code stored locally or remotely for access by single or multi-processor machines. In addition, in some embodiments the order of operations may be rearranged without departing from the spirit of the disclosed subject matter.

Processor device 504 may be a special purpose (e.g., a graphical processing unit) or a general-purpose processor device. As will be appreciated by persons skilled in the relevant art, processor device 504 may also be a single processor in a multi-core/multiprocessor system, such system operating alone, or in a cluster of computing devices operating in a cluster or server farm. Processor device 504 may be connected to a communication infrastructure 506, for example, a bus, message queue, network, or multi-core message-passing scheme.

In an exemplary embodiment, computer system 500 may include a display interface 502, for example a video connector, to transfer data to a display unit 530, for example, a monitor. Computer system 500 may also include a main memory 508, for example, random access memory (RAM), and may also include a secondary memory 510. Secondary memory 510 may include, for example, a hard disk drive 512, and a removable storage drive 514. Removable storage drive 514 may include a floppy disk drive, a magnetic tape drive, an optical disk drive, a flash memory, or the like. Removable storage drive 514 may read from and/or write to a removable storage unit 518 in a well-known manner. Removable storage unit 518 may include a floppy disk, a magnetic tape, an optical disk, etc., which may be read by and written to by removable storage drive 514. As will be appreciated by persons skilled in the relevant art, removable storage unit 518 may include a computer usable storage medium having stored therein computer software and/or data.

In alternative implementations, secondary memory 510 may include other similar means for allowing computer programs or other instructions to be loaded into computer system 500. Such means may include, for example, a removable storage unit 522 and an interface 520. Examples of such means may include a program cartridge and cartridge interface (such as that found in video game devices), a removable memory chip (such as an EPROM, or PROM) and associated socket, and other removable storage units 522 and interfaces 520 which allow software and data to be transferred from removable storage unit 522 to computer system 500.

Computer system 500 may also include a communications interface 524. Communications interface 524 allows software and data to be transferred between computer system 500 and external devices. Communications interface 524 may include a modem, a network interface (such as an Ethernet card), a communications port, a PCMCIA slot and card, or the like. Software and data transferred via communications interface 524 may be in the form of signals, which may be electronic, electromagnetic, optical, or other signals capable of being received by communications interface 524. These signals may be provided to communications interface 524 via a communications path 526. Communications path 526 carries signals and may be implemented using wire or cable, fiber optics, a phone line, a cellular phone link, an RF link or other communications channels.

In this document, the terms “computer program medium” and “computer usable medium” are used to generally refer to media such as removable storage unit 518, removable storage unit 522, and a hard disk installed in hard disk drive 512. Computer program medium and computer usable medium may also refer to memories, such as main memory 508 and secondary memory 510, which may be memory semiconductors (e.g. DRAMs, etc.).

Computer programs (also called computer control logic) are stored in main memory 508 and/or secondary memory 510. Computer programs may also be received via communications interface 524. Such computer programs, when executed, enable computer system 500 to implement different embodiments of the present disclosure as discussed herein. In particular, the computer programs, when executed, enable processor device 504 to implement the processes of the present disclosure, such as the operations of such as the operations in method 100 illustrated by flowchart 100 of FIG. 1A and flowchart 104 of FIG. 1B discussed above. Accordingly, such computer programs represent controllers of computer system 500. Where an exemplary embodiment of method 100 is implemented using software, the software may be stored in a computer program product and loaded into computer system 500 using removable storage drive 514, interface 520, and hard disk drive 512, or communications interface 524.

Embodiments of the present disclosure also may be directed to computer program products including software stored on any computer useable medium. Such software, when executed in one or more data processing device, causes a data processing device to operate as described herein. An embodiment of the present disclosure may employ any computer useable or readable medium. Examples of computer useable mediums include, but are not limited to, primary storage devices (e.g., any type of random access memory), secondary storage devices (e.g., hard drives, floppy disks, CD ROMS, ZIP disks, tapes, magnetic storage devices, and optical storage devices, MEMS, nanotechnological storage device, etc.).

The embodiments have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various implementations. This is for purposes of streamlining the disclosure, and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separately claimed subject matter.

While various implementations have been described, the description is intended to be exemplary, rather than limiting and it will be apparent to those of ordinary skill in the art that many more implementations and implementations are possible that are within the scope of the implementations. Although many possible combinations of features are shown in the accompanying figures and discussed in this detailed description, many other combinations of the disclosed features are possible. Any feature of any implementation may be used in combination with or substituted for any other feature or element in any other implementation unless specifically restricted. Therefore, it will be understood that any of the features shown and/or discussed in the present disclosure may be implemented together in any suitable combination. Accordingly, the implementations are not to be restricted except in light of the attached claims and their equivalents. Also, various modifications and changes may be made within the scope of the attached claims.

What is claimed is:

1. A method for spherical magnetic resonance imaging (MRI) based on three-dimensional (3D) radial data sampling, the method comprising:
acquiring, utilizing an MRI scanner, a plurality of frequency samples of an object in a spatial frequency domain according to a 3D radial sampling scheme; and
reconstructing, utilizing one or more processors, a 3D image of the object in a space domain by applying a spherical Fourier transform (SFT) to the plurality of frequency samples.

2. The method of claim 1, wherein acquiring the plurality of frequency samples according to the 3D radial sampling scheme comprises acquiring the plurality of frequency samples at regular intervals along a plurality of radial paths from a center of a 3D k-space.

3. The method of claim 2, wherein reconstructing the 3D image comprises:
obtaining a first vector of spherical harmonic coefficients by calculating a respective plurality of spherical harmonic coefficients in the spatial frequency domain for each of the plurality of frequency samples;
obtaining a second vector of spherical harmonic coefficients by calculating a spherical Hankel transform of the first vector, the second vector comprising a respective plurality of spherical harmonic coefficients in the space domain for each of a plurality of space samples of the 3D image; and
obtaining the 3D image by calculating a spherical harmonics expansion of each of the plurality of space samples based on the respective plurality of spherical harmonic coefficients in the space domain.

4. The method of claim 3, wherein obtaining the 3D image comprises calculating the spherical harmonics expansion of a function f(r,θᵣ,ϕᵣ) representing a space sample of the plurality of space samples at a radial space distance r, a polar angle θᵣ of the radial space distance r, and an azimuthal angle ϕᵣ of the radial space distance r in the space domain according to an operation defined by the following:
$$f ( r , {θ}_{r} , {ϕ}_{r} ) = {\sum }_{l = 0}^{L} {\sum }_{m = - l}^{l} {f}_{l}^{m} ( r ) {Y}_{l}^{m} ( {θ}_{r} , {ϕ}_{r} )$$
where:
L is an upper limit for the spherical harmonics expansion of the function f(r,θᵣ,ϕᵣ),
$${f}_{l}^{m} ( r )$$
is an (l, m)th spherical harmonic coefficient of the respective plurality of spherical harmonic coefficients in a spherical harmonic expansion of the function f(r,θᵣϕᵣ), and
Yᵢ^{m}(⋅) is a spherical harmonic function of order l and degree m.

5. The method of claim 4, wherein obtaining the 3D image further comprises calculating the upper limit L according to a given spatial resolution inside a limited spherical area of the 3D image.

6. The method of claim 5, wherein obtaining the 3D image further comprises calculating the upper limit L according to an operation defined by the following:
$$L > \frac{C}{2 {sin}^{- 1} ( \frac{res}{2 {r}_{0}} )}$$
where C is a constant, res is the given spatial resolution and r₀ is a radial distance associated with the given spatial resolution.

7. The method of claim 2, wherein acquiring the plurality of frequency samples according to the 3D radial sampling scheme further comprises determining one of a number of the plurality of radial paths or an angular distance between adjacent radial paths of the plurality of radial paths based on a radial distance associated with a given spatial resolution of the 3D image.

8. The method of claim 7, wherein acquiring the number of the plurality of frequency samples according to the 3D radial sampling scheme further comprises determining a statistical distribution for an angular distance ΔΨ between adjacent radial paths of the plurality of radial paths according to a set of operations defined by the following:
$$mean ( Δψ ) \leq 2 \times {sin}^{- 1} ( \frac{res}{2 {r}_{0}} )$$
$$std ( Δψ ) \leq 0.3 \times {sin}^{- 1} ( \frac{res}{2 {r}_{0}} )$$
where:
res is the given spatial resolution and r₀ is the radial distance,
mean (ΔΨ) is an average value of the angular distance, and
std (ΔΨ) is a standard deviation of the angular distance.

9. The method of claim 7, wherein acquiring the plurality of frequency samples according to the 3D radial sampling scheme further comprises:
arranging the plurality of radial paths according to a uniform angular distribution; and
determining the number N of the plurality of radial paths according to an operation defined by the following:
$$N \geq \frac{2 π}{K} {( \frac{2 {r}_{0}}{res} )}^{2}$$
where K is a constant.

10. A system for spherical magnetic resonance imaging (MRI) based on three-dimensional (3D) radial data sampling, the system comprising:
an MRI scanner;
a memory having processor-readable instructions stored therein; and
a processor configured to access the memory and execute the processor-readable instructions, which, when executed by the processor configures the processor to perform a method, the method comprising:
acquiring, utilizing the MRI scanner, a plurality of frequency samples of an object in a spatial frequency domain according to a 3D radial sampling scheme; and
reconstructing a 3D image of the object in a space domain by applying a spherical Fourier transform (SFT) to the plurality of frequency samples.

11. The system of claim 10, wherein acquiring the plurality of frequency samples according to the 3D radial sampling scheme comprises acquiring the plurality of frequency samples at regular intervals along a plurality of radial paths from a center of a 3D k-space.

12. The system of claim 11, wherein reconstructing the 3D image comprises:
obtaining a first vector of spherical harmonic coefficients by calculating a respective plurality of spherical harmonic coefficients in the spatial frequency domain for each of the plurality of frequency samples;
obtaining a second vector of spherical harmonic coefficients by calculating a spherical Hankel transform of the first vector, the second vector comprising a respective plurality of spherical harmonic coefficients in the space domain for each of a plurality of space samples of the 3D image; and
obtaining the 3D image by calculating a spherical harmonics expansion of each of the plurality of space samples based on the respective plurality of spherical harmonic coefficients in the space domain.

13. The system of claim 12, wherein obtaining the 3D image comprises calculating the spherical harmonics expansion of a function f(r,θᵣ,ϕᵣ) representing a space sample of the plurality of space samples at a radial space distance r, a polar angle θᵣ of the radial space distance r, and an azimuthal angle ϕᵣ of the radial space distance r in the space domain according to an operation defined by the following:
$$f ( r , {θ}_{r} , {ϕ}_{r} ) = {\sum }_{l = 0}^{L} {\sum }_{m = - l}^{l} {f}_{l}^{m} ( r ) {Y}_{l}^{m} ( {θ}_{r} , {ϕ}_{r} )$$
where:
L is an upper limit for the spherical harmonics expansion of the function f(r,θᵣ,ϕᵣ),
$${f}_{l}^{m} ( r )$$
is an (l, m)th in spherical harmonic coefficient of the respective plurality of spherical harmonic coefficients in a spherical harmonic expansion of the function f(r, θᵣ, ϕᵣ), and
$${Y}_{l}^{m} ( \cdot )$$
is a spherical harmomc function of order l and degree m.

14. The system of claim 13, wherein obtaining the 3D image further comprises calculating the upper limit L according to a given spatial resolution inside a limited spherical area of the 3D image.

15. The system of claim 14, wherein obtaining the 3D image further comprises calculating the upper limit L according to an operation defined by the following:
$$L > \frac{C}{2 {sin}^{- 1} ( \frac{res}{2 {r}_{0}} )}$$
where C is a constant, res is the given spatial resolution and r₀ is a radial distance associated with the given spatial resolution.

16. The system of claim 11, wherein acquiring the plurality of frequency samples according to the 3D radial sampling scheme further comprises determining one of a number of the plurality of radial paths or an angular distance between adjacent radial paths of the plurality of radial paths based on a radial distance associated with a given spatial resolution of the 3D image.

17. The system of claim 16, wherein acquiring the number of the plurality of frequency samples according to the 3D radial sampling scheme further comprises determining a statistical distribution for an angular distance ΔΨ between adjacent radial paths of the plurality of radial paths according to a set of operations defined by the following:
$$mean ( Δψ ) \leq 2 \times {sin}^{- 1} ( \frac{res}{2 {r}_{0}} )$$
$$std ( Δψ ) \leq 0.3 \times {sin}^{- 1} ( \frac{res}{2 {r}_{0}} )$$
where:
res is the given spatial resolution and r₀ is the radial distance,
mean (ΔΨ) is an average value of the angular distance, and
std (ΔΨ) is a standard deviation of the angular distance.

18. The system of claim 16, wherein acquiring the plurality of frequency samples according to the 3D radial sampling scheme further comprises:
arranging the plurality of radial paths according to a uniform angular distribution; and
determining the number N of the plurality of radial paths according to an operation defined by the following:
$$N \geq \frac{2 π}{K} {( \frac{2 {r}_{0}}{res} )}^{2}$$
where K is a constant.
